(19) United States
(12) Patent Application Publication
(10) Pub. No.: US 2025/0287688 A1
(43) Pub. Date: Sep. 11, 2025

(54) SEMICONDUCTOR DEVICE

(71) Applicant: Samsung Electronics Co., Ltd., Suwon-si (KR)

(72) Inventors: Sangjine PARK, Suwon-si (KR); Ilyoung YOON, Suwon-si (KR)

(73) Assignee: Samsung Electronics Co., Ltd., Suwon-si (KR)

(21) Appl. No.: 18/805,979

(22) Filed: Aug. 15, 2024

(30) Foreign Application Priority Data
Mar. 11, 2024 (KR) 10-2024-0033687

(51) Int. Cl. H01L 27/092; H01L 21/8238; H01L 29/06; H01L 29/08; H01L 29/423; H01L 29/66; H01L 29/775; H01L 29/786

(52) U.S. Cl. CPC H10D 84/85; H10D 30/014; H10D 30/43; H10D 30/6735; H10D 30/6757; H10D 62/121; H10D 62/151; H10D 84/0167; H10D 84/017; H10D 84/0188; H10D 84/038

(57) ABSTRACT

A semiconductor device may include a substrate including an active region extending in a first direction; a device isolation layer defining the active region; first and second gate electrodes extending in a second direction and spaced apart from each other; first channel layers apart from each other and surrounded by the first gate electrode; second channel layers apart from each other and surrounded by the second gate electrode; an insulating isolation pattern between the first and second gate electrodes and between the first and second channel layers; gate dielectric layers between the first channel layers and the first gate electrode and between the second channel layers and the second gate electrode; and epitaxial layers on opposing side surfaces of the first and second channel layers. Portions of the epitaxial layers may overlap the insulating isolation pattern, gate dielectric layers, and first and second gate electrodes in a third direction.

### CROSS-REFERENCE TO RELATED APPLICATION(S)

This application claims benefit of priority to Korean Patent Application No. 10-2024-0033687 filed on Mar. 11, 2024 in the Korean Intellectual Property Office, the disclosure of which is incorporated herein by reference in its entirety.

### BACKGROUND

Example embodiments of the present disclosure relate to a semiconductor device.

As demand for high performance, high speed, and/or multifunctionality for a semiconductor device has increased, integration density of a semiconductor devices has increased. To overcome limitations in operation properties caused by reduction of a size of a planar MOSFET (metal oxide semiconductor FET), there has been an effort for developing a semiconductor device including a FinFET including a fin-shaped channel and a gate-all-around field-effect transistor including nanosheets surrounded by a gate.

### SUMMARY

An example embodiment of the present disclosure is to provide a semiconductor device having improved electrical properties and reliability.

According to an example embodiment, a semiconductor device may include a substrate including a first region and a second region, the substrate including an active region extending in a first direction; a device isolation layer defining the active region, the device isolation layer being on the substrate; a first gate electrode and a second gate electrode extending in a second direction, the second direction intersecting the active region, the first gate electrode and the second gate electrode being spaced apart from each other; a plurality of first channel layers spaced apart from each other in a third direction, the third direction being perpendicular to an upper surface of the substrate, and the plurality of first channel layers being surrounded by the first gate electrode on the first region; a plurality of second channel layers spaced apart from each other in the third direction, the plurality of second channel layers being surrounded by the second gate electrode on the second region; an insulating isolation pattern extending in the first direction between the first gate electrode and the second gate electrode and between the plurality of first channel layers and the plurality of second channel layers, the insulating isolation pattern being on the substrate; gate dielectric layers between the plurality of first channel layers and the first gate electrode, and the gate dielectric layers between the plurality of second channel layers and the second gate electrode; and epitaxial layers on side surfaces of the plurality of first channel layers and the plurality of second channel layers that respectively oppose each other. A portion of each of the epitaxial layers may overlap the insulating isolation pattern, the gate dielectric layers, the first gate electrode, and the second gate electrode in the third direction.

According to an example embodiment, a semiconductor device may include a substrate including an active region extending in a first direction; a first gate electrode and a second gate electrode extending in a second direction, the second direction intersecting the active region, the first gate electrode and the second gate electrode being spaced apart from each other; a plurality of first channel layers spaced apart from each other in a third direction, the third direction perpendicular to an upper surface of the substrate, and the plurality of first channel layers being surrounded by the first gate electrode; a plurality of second channel layers spaced apart from each other in the third direction, the plurality of second channel layers being surrounded by the second gate electrode; an insulating isolation pattern between the plurality of first channel layers and the plurality of second channel layers, the insulating isolation pattern extending to a level lower than a level of an upper surface of the active region; first epitaxial layers on side surfaces of the plurality of first channel layers and the plurality of second channel layers, opposing each other, the first epitaxial layers being in contact with the insulating isolation pattern in the active region; and a second epitaxial layer in the active region of the substrate and having an upper surface in contact with the insulating isolation pattern.

According to an example embodiment, a semiconductor device may include a substrate including a first region and a second region, the substrate including an active region extending in a first direction; a first gate electrode and a second gate electrode extending in a second direction, the second direction intersecting the active region, the first gate electrode including a first conductive layer, the second gate electrode including a second conductive layer, the first gate electrode and the second gate electrode each including a third conductive layer, the first conductive layer and the third conductive layer of the first gate electrode being stacked in order, and the second conductive layer and the third conductive layer of the second gate electrode being stacked in order; a plurality of channel layers stacked in a third direction on the active region, the third direction being perpendicular to an upper surface of the substrate, and the plurality of channel layers overlapping the third conductive layer of the first gate electrode in the third direction; a gate dielectric layer covering a portion of each of the plurality of channel layers; an insulating isolation pattern between the first gate electrode and the second gate electrode; and a semiconductor material layer disposed on a side surface of at least one of the plurality of channel layers, wherein the first conductive layer and the second conductive layer may include different metal materials.

### BRIEF DESCRIPTION OF DRAWINGS

The and other aspects, features, and advantages in example embodiments will be more clearly understood from the following detailed description, taken in combination with the accompanying drawings, in which:

FIG. 1 is a plan diagram illustrating a semiconductor device according to an example embodiment of the present disclosure;

FIG. 2A is a cross-sectional diagram illustrating a semiconductor device taken along line I-I′ according to example embodiments of the present disclosure;

FIG. 2B is a cross-sectional diagram illustrating a semiconductor device taken along line II-II′ according to an example embodiment of the present disclosure;

FIG. 2C is a cross-sectional diagram illustrating a semiconductor device taken along line III-III′ according to an example embodiment of the present disclosure;

FIG. 3 is a cross-sectional diagram illustrating a semiconductor device according to example embodiments of the present disclosure;

FIG. 4 is a cross-sectional diagram illustrating a semiconductor device according to example embodiments of the present disclosure;

FIG. 5 is a cross-sectional diagram illustrating a semiconductor device according to example embodiments of the present disclosure;

FIG. 6 is a cross-sectional diagram illustrating a semiconductor device according to example embodiments of the present disclosure;

FIG. 7 is a cross-sectional diagram illustrating a semiconductor device according to example embodiments of the present disclosure; and

FIGS. 8A to 8I are diagrams illustrating processes of a method of manufacturing a semiconductor device according to example embodiments of the present disclosure.

### DETAILED DESCRIPTION

Hereinafter, embodiments in the example embodiment will be described as follows with reference to the accompanying drawings.

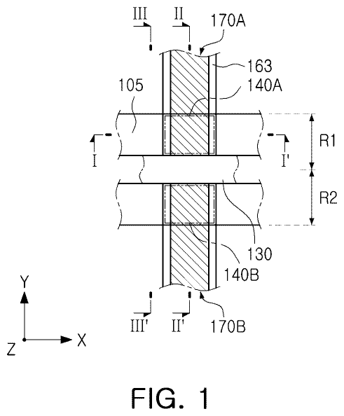

FIG. 1 is a plan diagram illustrating a semiconductor device 100 according to an example embodiment.

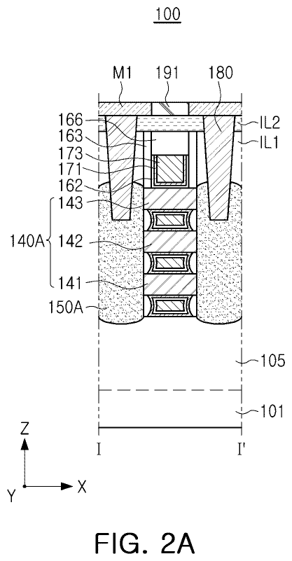

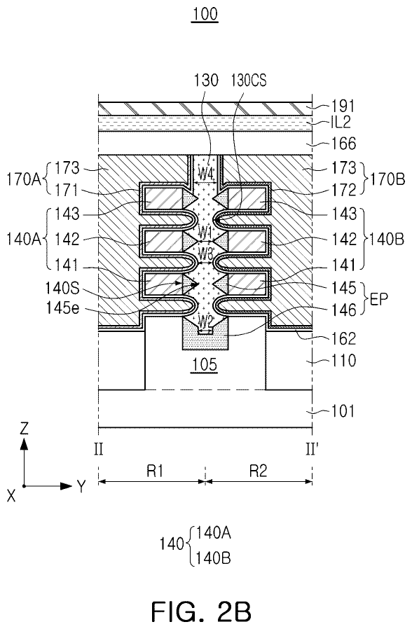

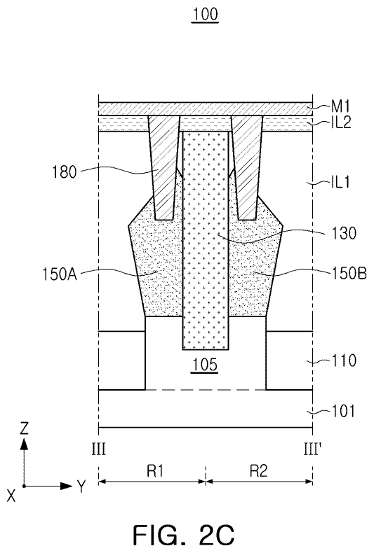

FIGS. 2A to 2C are cross-sectional diagrams illustrating the semiconductor device 100 according to example embodiment. FIG. 2A is a cross-sectional diagram illustrating the semiconductor device 100 taken along line I-I′ according to example embodiments; FIG. 2B is a cross-sectional diagram illustrating the semiconductor device 100 taken along line II-II′ according to an example embodiment; FIG. 2C is a cross-sectional diagram illustrating the semiconductor device 100 taken along line III-III′ according to an example embodiment.

Referring to FIGS. 1 to 2C, a semiconductor device 100 may include a substrate 101 having first and second regions R1 and R2, an active region 105 on the substrate 101, channel structures 140 including a plurality of channel layers 141, 142, and 143 vertically disposed and spaced apart from each other on the active region 105, a first gate electrode 170A and a second gate electrode 170B extending by intersecting the active region 105, an insulating isolation pattern 130 isolating the first gate electrode 170A from the second gate electrode 170B, semiconductor material layers EP, source/drain regions 150 in contact with the channel structures 140, and contact plugs 180 connected to the source/drain regions 150. The semiconductor device 100 may further include a device isolation layer 110, gate dielectric layers 162, gate spacer layers 163, gate capping layers 166, and first and second interlayer insulating layers IL1 and IL2.

In the semiconductor device 100, the active region 105 may have a fin structure, the first and second gate electrodes 170A and 170B may be disposed between the active region 105 and the channel structure 140, between the plurality of channel layers 141, 142, and 143 in the channel structure 140, and on the channel structure 140, and an insulating isolation pattern 130 may be disposed between the plurality of first and second channel layers spaced apart from each other in the horizontal direction. Accordingly, the semiconductor device 100 may include transistors with a multi-bridge channel FET (MBCFET™) structure, which is a gate-all-around (Gate-All-Around) type field effect transistor, or transistors having a forksheet structure including insulating pillars between a plurality of nanosheets.

The substrate 101 may have an upper surface extending in a first direction (e.g., X-axis direction) and a second direction (e.g., Y-axis direction). The substrate 101 may include a semiconductor material, such as a group IV semiconductor, a group III-V compound semiconductor, or a group II-VI compound semiconductor. For example, a group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer.

The substrate 101 may include first region R1 and second region R2, and the first and second regions R1 and R2 may be adjacent to each other. A portion of the active region 105, the source/drain regions 150, and the first gate electrode 170A may be disposed in the first region R1, and the other portion of the active region 105, the source/drain regions 150, and the second gate electrode 170B may be disposed in the second region R2. For example, in the first region R1, nFET (n-type Field Effect Transistor) may be disposed, and in the second region R2, pFET (p-type Field Effect Transistor) may be disposed. In some example embodiments, in the first and second regions R1 and R2, transistors having the same conductivity type and different electrical properties may be disposed.

The active region 105 may be defined by the device isolation layer 110 and may be disposed to extend in the first direction (e.g., X-axis direction). Depending on descriptions, the active region 105 may be described as a portion of the substrate 101. The active regions 105 may partially protrude to the device isolation layer 110, such that upper surfaces of the active region 105 may be disposed on a level higher than a level of an upper surface of the device isolation layer 110. The active regions 105 may include a portion of the substrate 101 or may include an epitaxial layer grown from the substrate 101. However, the active region 105 may be partially recessed to form recess regions on both sides of the first and second gate electrodes 170A and 170B, and the source/drain regions 150 having different conductivity types may be disposed in the recess regions.

In example embodiments, the region overlapping the first region R1 of the active region 105 may be referred to as a first active region, and the region overlapping the second region R2 of the active region 105 may be referred to as a second active region. Each of the first and second active regions may include well regions including impurities. For example, in the first active region of the first region R1 in which the nFET is disposed, the well region may include P-type impurities such as boron (B), gallium (Ga), or aluminum (Al). In the second active region of second region R2 in which the pFET is disposed, the well region may include N-type impurities such as phosphorus (P), arsenic (As), or antimony (Sb). For example, the well region may be disposed at a predetermined depth from an upper surface of each of the first and second active regions.

The device isolation layer 110 may define the active region 105 in the substrate 101. The device isolation layer 110 may be formed, for example, by a shallow trench isolation (STI) process. The device isolation layer 110 may expose the upper surface of active region 105 and may partially expose an upper portion. In some example embodiments, the device isolation layer 110 may have a curved upper surface to have a level increasing toward the active region 105. The device isolation layer 110 may be formed of an insulating material. The device isolation layer 110 may include, for example, oxide, nitride, or a combination thereof.

The channel structures 140 may include a plurality of first channel layers 140A spaced apart from each other in the third direction (e.g., Z-axis direction) perpendicular to an upper surface of substrate 101, and a plurality of second channel layers 140B spaced apart from each other in the third direction (e.g., Z-axis direction) perpendicular to the upper surface of the substrate 101 on the second region R2. The plurality of first channel layers 140A and the plurality of second channel layers 140B may be spaced apart from each other in the second direction (e.g., Y-axis direction). The channel structures 140 may be connected to the source/drain regions 150 (e.g., 150A, 150B) and may be spaced apart from the upper surface of the active region 105.

The plurality of channel layers 141, 142, and 143 may be formed of a semiconductor material, and may include, for example, at least one of silicon (Si), silicon germanium (SiGe), and germanium (Ge). For example, the plurality of channel layers 141, 142, and 143 may be formed of the same material as that of the substrate 101. In example embodiments, the plurality of channel layers 141, 142, and 143 may include an impurity region disposed in a region adjacent to the source/drain regions 150. The number of the channel layers 141, 142, and 143 of each of the channel structures 140 and the shape thereof may be varied in example embodiments.

The first source/drain region 150A and the second source/drain region 150B may be disposed on the first and second active regions on both sides of the first and second gate electrodes 170A and 170B and the channel structures 140, respectively. The first source/drain regions 150A may be disposed on the first active regions on both sides of the first gate electrode 170A, and the second source/drain regions 150B may be disposed on the second active regions on both sides of the second gate electrode 170B.

The first and second source/drain regions 150A and 150B may be disposed in recess regions partially recessed into an upper portion of the first and second active regions. The first and second source/drain regions 150A and 150B may be in contact with the first to third channel layers 141, 142, and 143 of the channel structures 140, and may be disposed to cover side surfaces of each of the plurality of channel layers 141, 142, and 143. Upper surfaces of the first and second source/drain regions 150A and 150B may be disposed on a level the same as or similar to a level of lower surfaces of the uppermost regions of the first and second gate electrodes 170A and 170B, and the level may be varied in example embodiments. In example embodiments, the first and second source/drain regions 150A and 150B may be connected or merged with each other on two or more first and second active regions adjacent to each other in the Y-direction, and may form the first and second source/drain regions 150A and 150B, respectively.

The first and second source/drain regions 150A and 150B may include impurities of different conductivity types. For example, the first source/drain regions 150A may include N-type impurities, and the second source/drain regions 150B may include P-type impurities, but an example embodiment thereof is not limited thereto.

The gate structure may include first and second gate electrodes 170A and 170B, a gate dielectric layer 162, gate spacer layers 163, and a gate capping layer 166.

The first gate electrode 170A and the second gate electrode 170B may intersect the active region 105 and the channel structures 140 and may extend in the second direction (e.g., Y-axis direction) on the active region 105 and the channel structures 140. Physical channel regions of transistors may be formed in the active region 105 and/or the channel structures 140 intersecting the first and second gate electrodes 170A and 170B. The first and second gate electrodes 170A and 170B may fill regions between the plurality of first channel layers 140A and the second channel layers 140B, respectively, on the active regions 105 and may extend to the channel structures 140. The first and second gate electrodes 170A and 170B may be spaced apart from the first to third channel layers 141, 142, and 143 by the gate dielectric layer 162.

The first and second gate electrodes 170A and 170B may be disposed linearly in the second direction (e.g., Y-axis direction). The first gate electrode 170A and the second gate electrode 170B may be disposed on the first and second regions R1 and R2, respectively, with the insulating isolation pattern 130 therebetween. The first gate electrode 170A may include first and third conductive layers 171 and 173 stacked in order, and the second gate electrode 170B may include second and third conductive layers 172 and 173 stacked in order. The first and second gate electrodes 170A and 170B may be included in nFET and pFET, respectively. Alternatively, the first and second gate electrodes 170A and 170B may be included in nFETs having different operating voltages, or pFETs having different operating voltages.

The first conductive layer 171 may be disposed on the gate dielectric layers 162 on the first region R1. The first conductive layer 171 may extend on the gate dielectric layers 162 extending conformally along a region between the plurality of first channel layers 140A, and may extend along an upper surface of the device isolation layer 110 and a side surface of insulating isolation pattern 130. The first conductive layer 171 may conformally extend along an upper surface, a side surface, and a lower surface of each of the plurality of first channel layers 140A. The third conductive layer 173 may be disposed on the first conductive layer 171 and may fill a space in the first conductive layer 171 in a cross-sectional surface. The first conductive layer 171 may have substantially the same thickness in regions other than the plurality of first channel layers 140A.

The notion that elements are “substantially the same” may indicate that the element may be completely the same and may also indicate that the elements may be determined to be the same in consideration of errors or deviations occurring during a process.

The second conductive layer 172 may be disposed on the gate dielectric layers 162 on the second region R2. The second conductive layer 172 may extend on the gate dielectric layers 162 extending conformally along a region between the plurality of second channel layers 140B, and may extend along an upper surface of the device isolation layer 110 and a side surface of the insulating isolation pattern 130. The second conductive layer 172 may conformally extend along an upper surface, a side surface, and a lower surface of each of the plurality of second channel layers 140B. The third conductive layer 173 may be disposed on the second conductive layer 172 and may fill a space in the second conductive layer 172 on a cross-sectional surface. The second conductive layer 172 may have substantially the same thickness in regions other than the plurality of second channel layers 140B.

The first and second gate electrodes 170A and 170B may be electrically isolated from each other by the insulating isolation pattern 130. The first and second gate electrodes 170A and 170B may have an internal stack structure symmetrical to each other with respect to the insulating isolation pattern 130, but an example embodiment thereof is not limited thereto.

The first and second gate electrodes 170A and 170B may include a conductive material, for example, a metal nitride such as titanium nitride (TiN), tantalum nitride (TaN), or tungsten nitride (WN), and/or may include a metal material such as aluminum (Al), tungsten (W), or molybdenum (Mo), or a semiconductor material such as doped polysilicon. The first conductive layer 171 may include a material different from that of the second and third conductive layers 172 and 173, and the second and third conductive layers 172 and 173 may include the same material or different materials. Even when the second and third conductive layers 172 and 173 may include the same material, the second and third conductive layers 172 and 173 may be formed in different processes, and an interfacial surface therebetween may be distinct.

For example, the first to third conductive layers 171, 172, and 173 may be metal layers. In an example embodiment, the second conductive layer 172 may have a work function equal to or smaller than that of the first conductive layer 171. For example, the first and second conductive layers 171 and 172 may be configured as metal layers for controlling the work function, and the first conductive layer 171 may include P-type metal and the second conductive layer 172 may include N-type metal. For example, the first conductive layer 171 may include at least one of TiAlN and TiN, and the second conductive layer 172 may include at least one of TiAlC and TiN, but an example embodiment thereof is not limited thereto.

The gate dielectric layers 162 may be disposed between the active region 105 and the first and second gate electrodes 170A and 170B, between the plurality of first channel layers 140A and the first gate electrode 170A, and between the plurality of second channel layers 140B and the second gate electrode 170B, and may be disposed to cover at least a portion of surfaces of the first and second gate electrodes 170A and 170B. For example, the gate dielectric layers 162 may be disposed to surround the entirety of surfaces other than upper surfaces of the first and second gate electrodes 170A and 170B. The gate dielectric layers 162 may extend to a region between the first and second gate electrodes 170A and 170B and the gate spacer layers 163, but an example embodiment thereof is not limited thereto.

The gate dielectric layers 162 may include oxide, nitride, or high-K material. The high-K material may refer to a dielectric material having a dielectric constant higher than that of a silicon oxide film ((SiO₂). The high-K material may include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In example embodiments, the gate dielectric layer 162 may include multiple films.

The gate spacer layers 163 may be disposed on both side surfaces of the first and second gate electrodes 170A and 170B, respectively. The first and second gate electrodes 170A and 170B may insulate the first and second source/drain regions 150A and 150B from the first and second gate electrodes 170A and 170B. The gate spacer layers 163 may be stacked and may form a multilayer structure. However, in some example embodiments, the gate spacer layer may include a single layer. The gate spacer layers 163 may include at least one of oxide, nitride, and oxynitride and, for example, may include a low dielectric constant film.

The gate capping layers 166 may be disposed on upper surfaces of the first and second gate electrodes 170A and 170B and an upper surface of the insulating isolation pattern 130. The gate capping layers 166 may include at least one of oxide, nitride, and oxynitride.

The insulating isolation pattern 130 may be disposed between the first gate electrode 170A and the second gate electrode 170B to isolate the first and second gate electrodes 170A and 170B from each other. An upper surface of the insulating isolation pattern 130 may be coplanar with upper surfaces of the first and second gate electrodes 170A and 170B. An upper surface of the insulating isolation pattern 130 may be exposed from the gate dielectric layers 162, the first conductive layer 171 and the second conductive layer 172 and may be covered by the gate capping layer 166. In some example embodiments, an upper surface of the insulating isolation pattern 130 may be covered with another layer formed of an insulating material, such as an interlayer insulating layer. Side surfaces of the insulating isolation pattern 130 may be perpendicular to an upper surface of the substrate 101 or may be inclined. In an example embodiment, the insulating isolation pattern 130 may have a shape tapered toward the substrate 101.

At least a portion of a side surface 130CS of the insulating isolation pattern 130, in the second direction (e.g., Y-axis direction), may have an inwardly concave shape on a level between channel layers 140 spaced apart from each other in the vertical direction. At least a portion of a side surface in the second direction of the insulating isolation pattern 130 may be in contact with the first epitaxial layer 145. The first epitaxial layer 145 may have a convex shape toward the insulating isolation pattern 130, and a side surface of the insulating isolation pattern 130 in the second direction may have a convex shape or a concave shape depending on a shape of the adjacent first epitaxial layer 145. The side surface of the insulating isolation pattern 130 in the second direction may have a serrated shape in which a convex shape and a concave shape are repeatedly formed. The gate dielectric layers 162, the first conductive layer 171 (or the second conductive layer 172) and the third conductive layer 173 may be stacked in order on the concave side surface of the insulating isolation pattern 130.

A shape of a lower surface of the insulating isolation pattern 130 may be varied depending on a shape of the adjacent second epitaxial layer 146. A lower surface of the insulating isolation pattern 130 may have a shape inclined toward the substrate 101 in a direction away from the first and second gate electrodes 170A and 170B. Among the lower surfaces of the insulating isolation pattern 130, a lower surface of a central portion adjacent to a boundary between the first region R1 and the second region R2 may have a convex shape toward the substrate 101. A lower surface of a central portion of the insulating isolation pattern 130 may have a shape surrounded by the second epitaxial layer 146. A lowermost end of the insulating isolation pattern 130 may be disposed on a level lower than a level of a lowermost end of the first and second gate electrodes 170A and 170B, and may be disposed on a level higher than a level of an uppermost end of the substrate 101.

A width of the insulating isolation pattern 130 in the second direction (e.g., Y-axis direction) between ends 145e of the first epitaxial layers 145 opposing each other may be referred to as a first width W1. A width of the portion in the second direction surrounded by the second epitaxial layer 146 of the insulating isolation pattern 130 may be referred to as a second width W2. A portion of the insulating isolation pattern 130, surrounded by the second epitaxial layer 146, may refer to a convex portion toward the substrate 101. Sizes of the first width W1 and the second width W2 may be substantially the same. Here, the notion that the sizes are the same may include process errors, and may indicate that a width may not be intentionally designed differently.

A width between the side surfaces 130CS of the insulating isolation pattern 130 opposing each other on a level between the channel layers 140, spaced apart from each other in the vertical direction, may be referred to as a third width W3. A width of the insulating isolation pattern 130 on a level higher than a level of the uppermost channel layer 143 among the plurality of channel layers 140 may be referred to as a fourth width W4. A size of the third width W3 may be substantially the same as a size of the first width W1. A size of the fourth width W4 may be the same as or greater than a size of the first width W1. As a level of the insulating isolation pattern 130 in the third direction (e.g., Z-axis direction) changes, changes in the size of the width may be repeated.

The insulating isolation pattern 130 may include an insulating material. The insulating isolation pattern 130 may include, for example, at least one of silicon oxide, silicon nitride, silicon oxynitride, and silicon carbide.

The semiconductor material layers EP may include first epitaxial layers 145 disposed on side surfaces of the plurality of first and second channel layers 140A and 140B opposing each other, and a second epitaxial layer 146 disposed in the active region 105.

The first epitaxial layers 145 may be disposed on side surfaces 140S on which the plurality of channel layers 140 oppose each other. Among the first epitaxial layers 145, the first epitaxial layer 145 on a side surface of the first channel layer 140A and the first epitaxial layer 145 on a side surface of the second channel layer 140B disposed on the same level may be spaced apart from each other by the insulating isolation pattern 130. other. A width of each of the first epitaxial layers 145 in the third direction (e.g., Z-axis direction) may decrease toward the insulating isolation pattern 130. In an example embodiment, a cross-sectional surface of each of the first epitaxial layers 145 may have a triangular shape of which a width in the third direction may decrease toward the insulating isolation pattern 130, but an example embodiment thereof is not limited thereto. In an example embodiment, the cross-sectional surface of the first epitaxial layers 145 may have a triangular shape of which ends 145e opposing each other correspond to apexes.

The second epitaxial layer 146 may be disposed on the substrate 101. A width of the second epitaxial layer 146 in the second direction (e.g., the Y-axis direction) may be substantially the same as a width from an interfacial surface between the first channel layers 140A and the first epitaxial layer 145 to an interfacial surface between the second channel layers 140B and the first epitaxial layer 145. Here, the notion that the sizes are the same may include process errors, and may indicate that a width is not intentionally designed differently. An upper surface of the second epitaxial layer 146 may have a partially inclined shape. Among upper surfaces of the second epitaxial layer 146, an upper surface of a central portion adjacent to a boundary between the first region R1 and the second region R2 may have a concave shape toward the substrate 101. An upper surface of a central portion of the second epitaxial layer 146 may have a shape surrounding the insulating isolation pattern 130. An upper surface of the second epitaxial layer 146 may be in contact with the insulating isolation pattern 130.

The first epitaxial layer 145 and the second epitaxial layer 146 may include the same material, and in an example embodiment, the first epitaxial layer 145 and the second epitaxial layer 146 may include selectively epitaxially grown silicon (Si). In an example embodiment, the first epitaxial layer 145 may include the same material as that of the plurality of channel layers 140, and a boundary of the surface on which the first epitaxial layer 145 and the channel layer 140 meet may not be distinct. In example embodiments, the first epitaxial layer 145 may correspond to a protrusion formed on the plurality of channel layers.

At least a portion of each of the first epitaxial layers 145 may overlap the insulating isolation pattern 130, the gate dielectric layers 162, the first and second gate electrodes 170A and 170B in the third direction (e.g., Z-axis direction), respectively. Among the plurality of first channel layers 140A, the third conductive layer 173 may overlap at least a portion of the first epitaxial layer 145 in the third direction. The semiconductor device in the example embodiment, by forming a first epitaxial layer 145 extending from a side surface of the plurality of channel layers 140 and including the first and second gate electrodes 170A and 170B extending inwardly of the insulating isolation pattern 130, an effective area and a length of the channel layers 140 may be lengthened, such that electrical signal transmission may be smoothly performed, thereby improving electrical properties and reliability of the semiconductor device 100.

The first interlayer insulating layer IL1 may cover source/drain regions 150. The first interlayer insulating layer IL1 may include at least one of oxide, nitride, and oxynitride, and may include, for example, a low dielectric constant material. In example embodiments, the first interlayer insulating layer IL1 may include a plurality of insulating layers.

The contact plugs 180 may penetrate the first interlayer insulating layer IL1, may be connected to the source/drain regions 150, and may apply an electrical signal to the source/drain regions 150. The contact plugs 180 may have an inclined side surface on which a width of the lower portion may decrease further than a width of the upper portion depending on the aspect ratio, but an example embodiment thereof is not limited thereto. The contact plugs 180 may extend downwardly, for example, to a region below a lower surface of the channel layer 143 of an uppermost first channel layer of the plurality of first channel layers 140A, but an example embodiment thereof is not limited thereto. In some example embodiments, the contact plugs 180 may not recess source/drain regions 150, and may be in contact with upper surfaces of the source/drain regions 150.

Each of the contact plugs 180 may include a metal-semiconductor compound layer, for example, a metal silicide layer, disposed on a lower end including a lower surface, and may further include a barrier layer forming side surfaces of the contact plug 180 and extending to an upper surface of the metal-semiconductor compound layer. For example, the barrier layer may include a metal nitride such as titanium nitride (TiN), tantalum nitride (TaN), or tungsten nitride (WN). The contact plugs 180 may include a metal material such as aluminum (Al), tungsten (W), or molybdenum (Mo). In example embodiments, the number of the conductive layers included in the contact plugs 180 and the arrangement form thereof may be varied.

An interconnection structure such as a contact plug may be further disposed on the first and second gate electrodes 170A and 170B, and an interconnection structure such as an interconnection line M1 connected to the contact plugs 180 may be further disposed on the contact plugs 180.

In the description in the example embodiments below, descriptions overlapping the descriptions described above with reference to FIGS. 1 to 2C may not be provided.

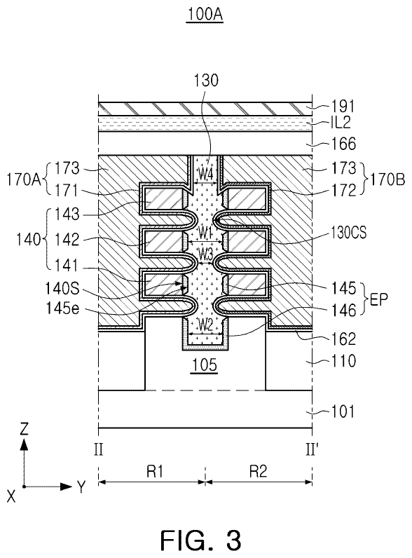

FIG. 3 is a cross-sectional diagram illustrating a semiconductor device according to example embodiments, illustrating a region corresponding to FIG. 2B.

Referring to FIG. 3, a semiconductor device 100A in an example embodiment may be configured the same as the example described with reference to FIGS. 1 to 2C, other than the configuration in which a cross-sectional surface of the first epitaxial layer 145 has a trapezoid shape. The semiconductor device 100A may include a first epitaxial layer 145 of which the cross-sectional surface has a trapezoidal shape. A width of the first epitaxial layer 145 of the semiconductor device 100A in the second direction (e.g., Y-axis direction) may be smaller than a width of the first epitaxial layer 145 of the semiconductor device 100 (see FIG. 2B) in the second direction. In the semiconductor device 100A in the example embodiment, an end 145e of the first epitaxial layer 145 may be substantially parallel to a side surface 140S on which the channel layers 140 oppose each other. The first epitaxial layer 145 may have a shape of which a width in the third direction (e.g., the Z-axis direction) may decrease toward the insulating isolation pattern 130. A width of the second epitaxial layer 146 of the semiconductor device 100A in the second direction (e.g., the Y-axis direction) and the third direction (e.g., the Z-axis direction) from an interfacial surface with the active region 105 may be smaller than a width in the second and third directions from an interfacial surface from the active region 105 of the second epitaxial layer 146 of the semiconductor device (100, see FIG. 2B). In example embodiments, a cross-sectional surface of each of the first epitaxial layers 145 may have a quadrangular shape. In an example embodiment, the first epitaxial layer 145 may have a rectangular cross-sectional surface shape of which a width may be constantly maintained in the third direction.

Referring to FIG. 3 together with FIG. 2B, a side surface of the insulating isolation pattern 130 may have a serrated shape in which a convex shape and a concave shape are repeated along shapes of the first epitaxial layer 145, the first gate electrode 170A and the second gate electrode 170B, in contact with each other. A first width W1 of a portion of the insulating isolation pattern 130 between ends 145e of the first epitaxial layers 145 opposing each other may be substantially equal to a second width W2 of a portion of the insulating isolation pattern 130 surrounded by the second epitaxial layer 146. Here, the configuration in which the sizes are the same may include process errors and may indicate that the width is not intentionally designed differently. The first width W1 and second width W2 of the insulating isolation pattern 130 in the semiconductor device 100A may be greater than the first width W1 and the second width W2 of the insulating isolation pattern 130 in the semiconductor device (100, see FIG. 2B). The first width W1 and the second width W2 of the insulating isolation pattern 130 in the semiconductor device 100A may be greater than a fourth width W4. On a level between the channel layers 140 spaced apart from each other in the vertical direction, the third width W3 between the side surfaces 130CS of the insulating isolation pattern 130, opposing each other, may be smaller than the first width W1.

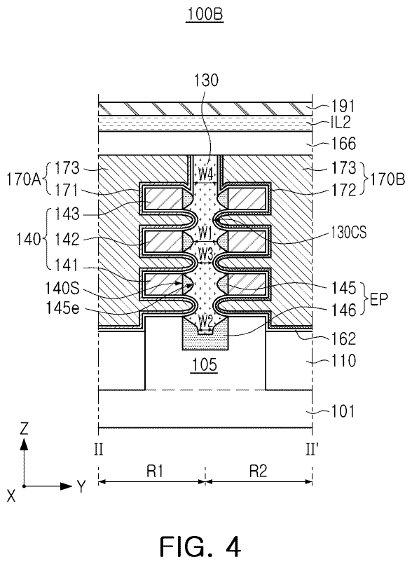

FIG. 4 is a cross-sectional diagram illustrating a semiconductor device according to example embodiments, illustrating a region corresponding to FIG. 2B.

Referring to FIG. 4, a semiconductor device 100B in an example embodiment may be configured the same as the example described with reference to FIGS. 1 to 3, other than the configuration in which one end 145e of the first epitaxial layer 145 has a rounded shape. The semiconductor device 100B may include a first epitaxial layer 145 of which a width in the third direction (e.g., the Z-axis direction) may decrease toward the insulating isolation pattern 130. In the semiconductor device 100B in the example embodiment, the end 145e of the first epitaxial layer 145 may have a circular shape or a rounded shape.

A first width W1 of the portion of the insulating isolation pattern 130 between the ends 145e of the first epitaxial layers 145, opposing each other, may be the same as or greater than a second width W2 of a portion of the insulating isolation pattern 130 surrounded by the second epitaxial layer 146. A fourth width W4 of the insulating isolation pattern 130 in the semiconductor device 100B may be substantially the same as or greater than the first width W1. The first width W1 and the second width W2 of the insulating isolation pattern 130 in the semiconductor device 100B may be greater than the first width W1 and the second width W2 of the insulating isolation pattern 130 in the semiconductor device 100 (see FIG. 2B). On a level between channel layers 140 spaced apart from each other in the vertical direction, the third width W3 between the side surfaces 130CS of the insulating isolation pattern 130, opposing each other, may be smaller than the first width W1.

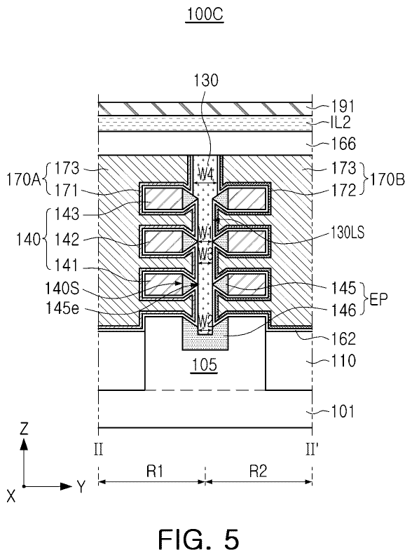

FIG. 5 is a cross-sectional diagram illustrating a semiconductor device according to example embodiments, illustrating a region corresponding to FIG. 2B.

Referring to FIG. 5, a semiconductor device 100C in an example embodiment may be configured the same as or similar to the example described with reference to FIGS. 1 to 4, other than the configuration in which at least a portion 130LS of the side surface of the insulating isolation pattern 130 extends linearly along ends 145e of the first epitaxial layers 145 in the second direction. In the semiconductor device 100C, at least a portion 130LS of the side surface of the insulating isolation pattern 130 may be configured to extend in the third direction (e.g., Z-axis direction) along the ends 145e of the first epitaxial layers 145 in the second direction (e.g., Y side direction). The side surface 130LS of the insulating isolation pattern 130 may be substantially parallel to the side surfaces 140S of the plurality of channel layers 140, opposing each other.

The first width W1 of a portion of the insulating isolation pattern 130 between the ends 145e of the first epitaxial layers 145, opposing each other, may be substantially the second width W2 of the portion of the insulating isolation pattern 130 surrounded by the second epitaxial layer 146. On a level between the channel layers 140 spaced apart from each other in the vertical direction, a third width W3 between side surfaces 130CS of the insulating isolation pattern 130, opposing each other, may be substantially the same as the first width W1. A fourth width W4 of the insulating isolation pattern 130 in the semiconductor device 100C may be greater than the first width W1, the second width W2 and the third width W3. As another example, the fourth width W4 of the insulating isolation pattern 130 in the semiconductor device 100C may be substantially the same as the first width W1, the second width W2 and the third width W3. Here, the configuration in which the sizes are the same may include process errors, and may indicate that the width is not intentionally designed differently. The insulating isolation pattern 130 may have a shape of which a width may be constant in the second direction (e.g., Y-axis direction) in a region from the ends 145e of an uppermost first epitaxial layers 145 to the second epitaxial layer 146.

The gate dielectric layers 162, a first conductive layer 171 and a third conductive layer 173 may be stacked in order on at least a portion of the side surface 130LS of the insulating isolation pattern 130, and the gate dielectric layers 162 and the first conductive layer 171 may conformally extend along the side surface 130LS of the insulating isolation pattern 130. The second conductive layer 172 may be configured the same as or similar to the first conductive layer 171.

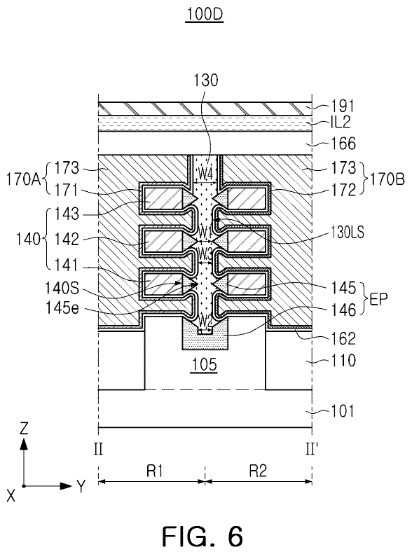

FIG. 6 is a cross-sectional diagram illustrating a semiconductor device according to example embodiments, illustrating a region corresponding to FIG. 2B.

Referring to FIG. 6, a semiconductor device 100D in an example embodiment may be configured the same as or similar to the example described with reference to FIGS. 1 to 5, other than the configuration in which the ends of the first epitaxial layers 145, opposing each other, are not in contact with the gate dielectric layers 162. In the semiconductor device 100D, at least a portion 130LS of the side surface of the insulating isolation pattern 130 may extend parallel to the side surface 140S on which the plurality of channel layers 140 oppose each other, and the ends 145e of the first epitaxial layers 145 opposing each other may not be in direct contact with the gate dielectric layers 162, and may be spaced apart from each other. In the semiconductor device 100D, the end 145e of the first epitaxial layers 145 may be in contact with the insulating isolation pattern 130. The relationship between the first width W1, the second width W2, the third width W3 and the fourth width W4 of the insulating isolation pattern 130 in the semiconductor device 100D may be the same as the relationship between the first width W1, the second width W2, the third width W3 and the fourth width W4.

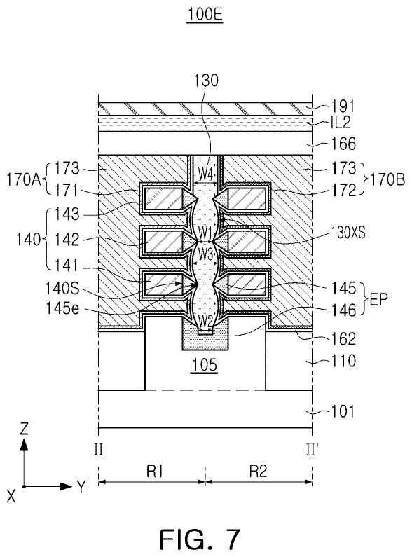

FIG. 7 is a cross-sectional diagram illustrating a semiconductor device according to example embodiments, illustrating a region corresponding to FIG. 2B.

Referring to FIG. 7, the semiconductor device 100E in an example embodiment may be configured the same as or similar to the example described with reference to FIGS. 1 to 6 other than the configuration in which at least a portion of the side surface 130XS of the insulating isolation pattern 130 has a convex shape on a level between the plurality of first channel layers 140A. In the semiconductor device 100E, a width of the insulating isolation pattern 130 in the second direction (e.g., the Y-axis direction) may not be uniform. The width of the insulating isolation pattern 130 in the second direction may be widest on a level between the plurality of first channel layers 140A or the plurality of second channel layers 140B, and may have a shape decreasing toward the end 145e of the first epitaxial layers 145. The side surface of the insulating isolation pattern 130 in the second direction may have a concave shape between the plurality of channel layers 140 disposed on the same level, and may have a convex shape between the first epitaxial layer 145, disposed on a level adjacent thereto, and the lowermost first epitaxial layer 145 and the second epitaxial layer 146, disposed on a lowest level among the first epitaxial layers 145. The side surface of the insulating isolation pattern 130 in the second direction may have a serrated shape in which the concave shape and the convex shape described above are repeated.

On a level between the channel layers 140 spaced apart from each other in the vertical direction, the third width W3 between the side surfaces 130CS of the insulating isolation pattern 130, opposing each other, may be larger than the first width W1 of the portion of the insulating isolation pattern 130 between the ends 145e of the first epitaxial layers 14, opposing each other.

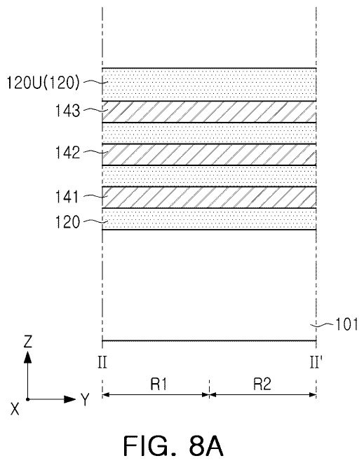

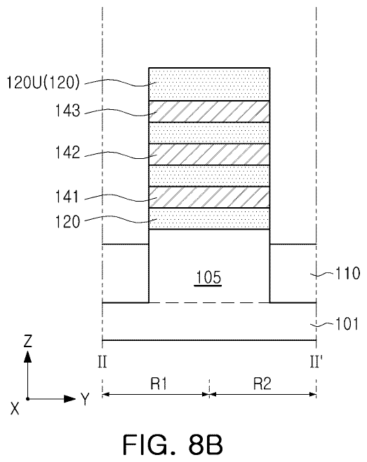

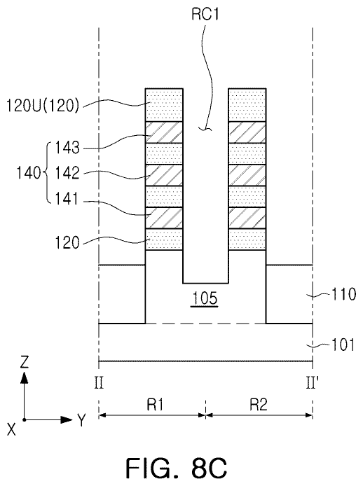

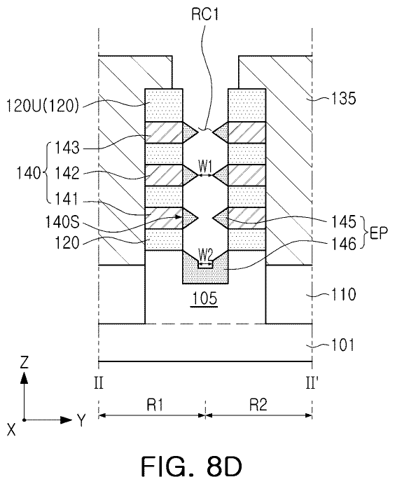

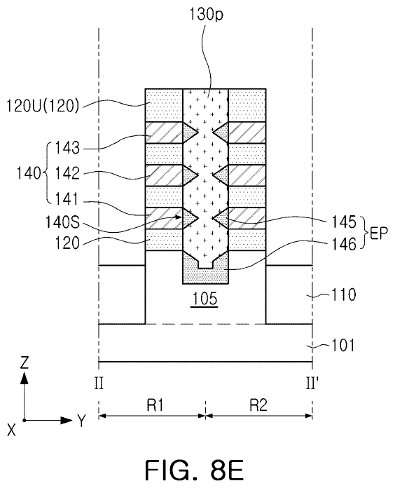

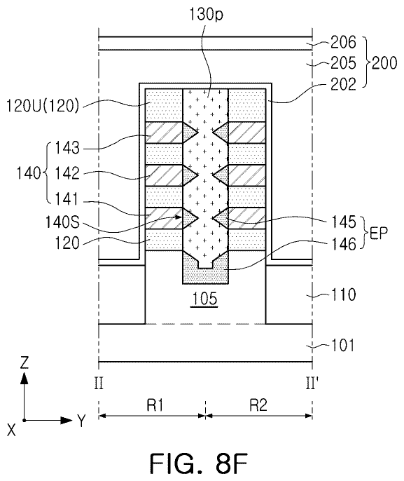

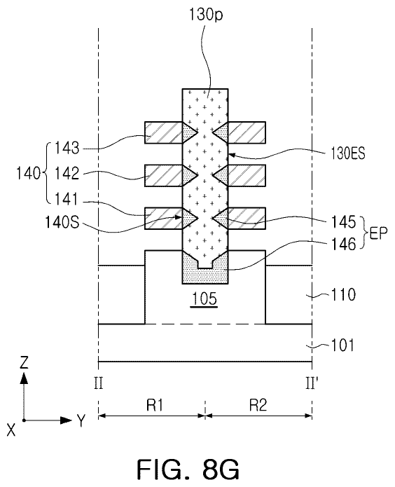

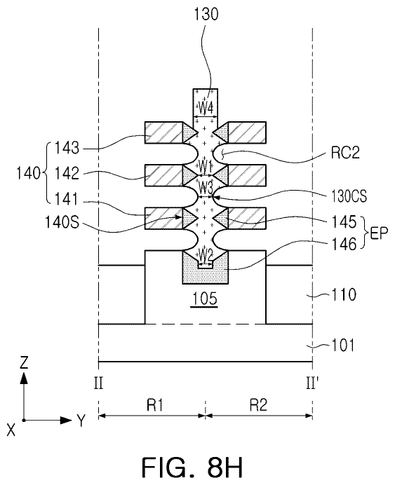

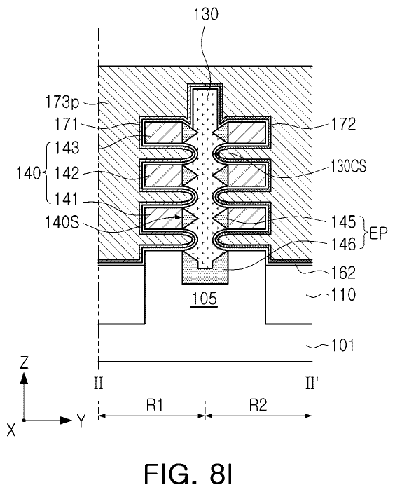

FIGS. 8A to 8I are diagrams illustrating processes of a method of manufacturing a semiconductor device according to example embodiments. FIGS. 8A to 8I illustrate an example embodiment of the method of manufacturing a semiconductor device 100 in FIGS. 1 to 2B. FIGS. 8A to 8I illustrate cross-sectional surfaces taken along lines II-II′ in FIG. 1.

Referring to FIG. 8A, sacrificial layers 120 and a plurality of channel layers 141, 142, and 143 may be alternately stacked on a substrate 101.

The sacrificial layers 120 may be replaced with the gate dielectric layers 162 and the first and second gate electrodes 170A and 170B through a subsequent process, as illustrated in FIGS. 2A and 2B. Sacrificial layers 120 may be formed of a material having etch selectivity for the first to third channel layers 141, 142, and 143, respectively. The first to third channel layers 141, 142, and 143 may include a material different from that of the sacrificial layers 120. The sacrificial layers 120 and the first to third channel layers 141, 142, and 143 may include, for example, a semiconductor material including at least one of silicon (Si), silicon germanium (SiGe), and germanium (Ge), may include different materials, and may or may not include impurities. For example, the sacrificial layers 120 may include silicon germanium (SiGe), and the first to third channel layers 141, 142, and 143 may include silicon (Si).

The sacrificial layers 120 and the first to third channel layers 141, 142, and 143 may be formed by performing an epitaxial growth process from the substrate 101. The number of channel layers 141, 142, and 143 alternately stacked with the sacrificial layers 120 may be varied in example embodiments. A thickness of the sacrificial layer 120U disposed on an uppermost end among the plurality of sacrificial layers 120 may be greater than a thickness of the other sacrificial layers 120, but an example embodiment thereof is not limited thereto.

Referring to FIG. 8B, active structures may be formed by removing a portion of the sacrificial layers 120, the plurality of channel layers 141, 142, and 143, and the substrate 101, and the device isolation layer 110 may be formed.

The active structures may include sacrificial layers 120 and a plurality of channel layers 141, 142, and 143 alternately stacked, and may further include an active region 105 protruding from the substrate 101 by removing a portion of the substrate 101. The active structures may be formed in a line shape extending in the first direction (e.g., X-axis direction) and may be spaced apart from each other in the second direction (e.g., Y-direction). In example embodiments, when the active region 105 is divided into first and second active regions, the first and second active regions may include the same or different impurities, and the impurities may be doped in the substrate 101 before the sacrificial layers 120 and the plurality of channel layers 141, 142, and 143 are formed.

In the region from which a portion of the substrate 101 has been removed, the device isolation layer 110 may be formed by filling the insulating material and partially removing the insulating material such that the active region 105 may protrude. An upper surface of the device isolation layer 110 may be formed on a level lower than a level of an upper surface of the active region 105.

Referring to FIG. 8C, a first recess region RC1 penetrating the sacrificial layers 120 and the channel layers 140 and extending in the third direction (e.g., Z-axis direction) may be formed on the active structure. The first recess region RC1 may be formed by patterning the sacrificial layers 120 and the channel layers 140. The first recess region RC1 may be configured as a trench region extending in the first direction (e.g., X-axis direction) along the active structure. The first recess region RC1 may extend into the substrate 101, and the first recess region RC1 may overlap at least a portion of each of the first region R1 and the second region R2 of the substrate 101 in the second direction (e.g., the Y-axis direction).

Referring to FIG. 8D, a mask layer 135 may be disposed on both sides of the active structure, and in the first recess region RC1, a first epitaxial layer 145 may be formed on an internal side surface 140S of each of the plurality of channel layers 140, and a second epitaxial layer 146 may be formed on an internal side surface of the active structure.

The mask layer 135 may cover both side surfaces of the active structure and at least a portion of the upper surface of the active structure. The mask layer 135 may extend in the first direction (e.g., X-axis direction), parallel to the active structure. The mask layer 135 may not cover the first recess region RC1, and may cover both side surfaces of the active structure to prevent silicon (Si) from epitaxially growing on both side surfaces in a subsequent process. Side surfaces in the first recess region RC1 on side surfaces of the channel layers 140 may be exposed from the mask layer 135. The first epitaxial layer 145 and the second epitaxial layer 146 may be formed through an epitaxial growth process on one side surface of the channel layers 140 in the first recess region RC1, and may include the same material. For example, the first epitaxial layer 145 and the second epitaxial layer 146 may include silicon (Si). The first epitaxial layer 145 and the second epitaxial layer 146 may have a cross-sectional surface having a triangular shape, as illustrated, but an example embodiment thereof is not limited thereto, and The first epitaxial layer 145 and the second epitaxial layer 146 may have a cross-sectional surface having a trapezoidal shape (see FIG. 3). Also, after the first epitaxial layer 145 and the second epitaxial layer 146 are formed, a portion of etching or other removal processes may be performed. For example, by removing a portion of the end 145e of the first epitaxial layer 145, the semiconductor device (100B, see FIG. 4) of another example embodiment including the first epitaxial layer 145 having a rounded semicircular shape may be formed. A distance in the second direction (e.g., Y-axis direction) between the ends 145e of the first epitaxial layers 145, opposing each other, may be referred to as a first width W1. At least a portion of an upper surface of the second epitaxial layer 146 may have a concave shape toward the substrate 101 in a central portion adjacent to a boundary between the first region R1 and the second region R2. A width of the concave region of the second epitaxial layer 146 in the second direction may be referred to as a second width W2. A size of the first width W1 may be the same as a size of the second width W2, but an example embodiment thereof is not limited thereto. Depending on the degree to which the semiconductor material layers EP are formed, the first width W1 and the second width W2 may be determined, and the semiconductor device in the various example embodiments described above may be formed.

Referring to FIG. 8E, a preliminary insulating isolation pattern 130p may be formed by filling the first recess region RC1 with an insulating material, and the mask layer (135, see FIG. 8D) may be removed.

The insulating material may include silicon oxide, silicon nitride, silicon oxynitride, or silicon carbide. The preliminary insulating isolation pattern 130p may be formed on the active structure in the active region 105, and may have a shape extending in the first direction (e.g., the X-axis direction) along the active structure. The preliminary insulating isolation pattern 130p formed according to the process in which the insulating material fills the first recess region (RC1, see FIG. 8D) may cover the first epitaxial layer 145 and the second epitaxial layer 146. An upper surface of the preliminary insulating isolation pattern 130p may be coplanar with an upper surface of the uppermost sacrificial layer 120U. In the subsequent process, by removing the mask layer 135 covering both side surfaces of the active structure and at least a portion of the upper surface, both side surfaces and upper surfaces of the active structure may be exposed, and at least a portion of the upper surface of the device isolation layer 110 may be exposed.

Referring to FIG. 8F, a sacrificial gate structure 200 and gate spacer layers 163 (see FIG. 2A) may be formed on the active structure.

The sacrificial gate structure 200 may be configured as a sacrificial structure formed in a region in which the gate dielectric layers 162 and the first and second gate electrodes 170A and 170B are disposed on the channel structures 140 through a subsequent process, as illustrated in FIGS. 2A and 2B. The sacrificial gate structure 200 may have a line shape intersecting the active structures and extending in one direction. The sacrificial gate structure 200 may extend, for example, in the Y-direction.

The sacrificial gate structure 200 may include first and second sacrificial gate layers 202 and 205 and a mask pattern layer 206 stacked in order. The first and second sacrificial gate layers 202 and 205 may be patterned using the mask pattern layer 206. The first and second sacrificial gate layers 202 and 205 may be configured as an insulating layer and a conductive layer, respectively, but an example embodiment thereof is not limited thereto, and the first and second sacrificial gate layers 202 and 205 may be configured as an integrated layer. For example, the first sacrificial gate layer 202 may include silicon oxide, and the second sacrificial gate layer 205 may include polysilicon. The mask pattern layer 206 may include silicon oxide and/or silicon nitride.

The gate spacer layers (163, see FIG. 2A) may be formed in order on both sidewalls of the sacrificial gate structure 200. The gate spacer layers 163 may be formed of a low dielectric constant material and each of the gate spacer layers 163 may include at least one of SiO, SiN, SiCN, SiOC, SiON, and SiOCN, for example.

First, recess regions may be formed by removing a portion of the exposed sacrificial layers 120 and plurality of channel layers 141, 142, and 143 using the sacrificial gate structure 200 and gate spacer layers 163 as a mask. Accordingly, the plurality of channel layers 141, 142, and 143 may form channel structures 140 having a limited length in the first direction (e.g., X-axis direction).

Thereafter, source/drain regions 150 may be formed by growing from the side surfaces of the active regions 105 and the channel structures 140, for example, by a selective epitaxial process. The source/drain regions (150, see FIGS. 2A and 2C) may include impurities due to in-situ doping and may include a plurality of layers having different doping elements and/or doping concentrations.

Referring to FIG. 8G, the interlayer insulating layer IL1 may be formed, and the sacrificial layers 120 and the sacrificial gate structure 200 may be removed.

The interlayer insulating layer 190 may be formed by forming an insulating film covering the sacrificial gate structure 200 and the source/drain regions 150 and performing a planarization process.

The sacrificial layers 120 and the sacrificial gate structure 200 may be selectively removed with respect to the gate spacer layers 163, the interlayer insulating layer (IL1, see FIG. 2A), and the channel structures 140. First, an upper gap region (not illustrated) may be formed by removing the sacrificial gate structure 200, and lower gap regions (not illustrated) may be formed by removing the sacrificial layers 120 exposed through the upper gap region. For example, when the sacrificial layers 120 include silicon germanium (SiGe) and the channel structures 140 include silicon (Si), the sacrificial layers 120 may be selectively removed by performing a wet etching process. Depending on the process of removing the sacrificial layers 120, the side surface 130ES of the preliminary insulating isolation pattern 130p in contact with the sacrificial layers 120 may be exposed from the plurality of channel layers 141, 142, and 143.

Referring to FIG. 8H, a second recess region RC2 and an insulating isolation pattern 130 may be formed by removing a portion of the preliminary insulating isolation pattern 130p.

A portion of the exposed side surface (130ES, see FIG. 8G) of the preliminary insulating isolation pattern 130p may be removed by a dry etching process. When removed by a dry etching process, as illustrated in FIG. 8H, a portion 130CS of the insulating isolation pattern 130 on the side surface may have a concave shape, but an example embodiment thereof is not limited thereto. In an example embodiment, when an ALE (Atomic Layer Etching) process is performed, the etching process may be performed parallel to the exposed surface 130ES of the preliminary insulating isolation pattern 130p, and the side surface of the insulating isolation pattern 130 may have a linearly extending shape (130LS, see FIG. 5). When the ALE process is performed, the etching speed may not be necessarily constant in the surface direction, and etching may be performed faster in the central portion. In this case, the semiconductor device (100D, see FIG. 6) in which the etching process has been performed less on an outer region of the exposed surface 130ES of the preliminary insulating isolation pattern 130p may be formed. In another example embodiment, the etching process may be performed faster along the surface on the upper surface and the lower surface of the channel layers 140, and in this case, the semiconductor (100E, see FIG. 7) in which the etching process is further performed on the outer region of the exposed surface 130ES of the preliminary insulating isolation pattern 130p may be formed. By the process of forming the second recess region RC2 by removing a portion of the preliminary insulating isolation pattern 130p, a third width W3 between the side surfaces 130CS of the insulating isolation pattern 130 opposing each other may be determined on a level between the channel layers 140 vertically spaced apart from each other. The fourth width W4 of the insulating isolation pattern 130 on a level higher than a level of the uppermost channel layer 143 among the plurality of channel layers 140 may be greater than the third width W3, but an example embodiment thereof is not limited thereto. By the process of forming the second recess region RC2, the semiconductor device of various example embodiments described above may be formed.

Referring to FIG. 8I, gate dielectric layers 162 may be formed, a first conductive layer 171 and a second conductive layer 172 may be formed, and a preliminary third conductive layer 173p may be formed.

The gate dielectric layers 162 may be formed to conformally cover a side surface, a lower surface and an upper surface of the plurality of channel layers 140 and a side surface of the insulating isolation pattern 130 on the first and second regions R1 and R2. The gate dielectric layers 162 may be formed to cover both the first region R1 and the second region R2 of the substrate 101. The first conductive layer 171 may be formed on the first region R1, and the second conductive layer 172 may be deposited on the second region R2. Using a mask pattern (not illustrated), the first conductive layer 171 and the second conductive layer 172 may be formed on the insulating isolation pattern 130 such that one side surface may be in contact with. The first conductive layer 171 and the second conductive layer 172 may control a work function and may include different metals, but an example embodiment thereof is not limited thereto. A preliminary third conductive layer 173p may be formed on the first conductive layer 171 and the second conductive layer 172. The preliminary third conductive layer 173p may fill a region between the plurality of first channel layers 140A and the plurality of second channel layers 140B, and may overlap the first epitaxial layers 145 in the third direction (e.g., the Z-axis direction). The preliminary third conductive layer 173p may extend further than the side surface 140S of the plurality of channel layers 140 opposing each other.

Thereafter, referring to FIGS. 2A to 2C, in a subsequent process, a third conductive layer 173, gate capping layers 166, and contact plugs 180 may be formed, thereby forming the semiconductor device 100 in the example embodiment.

The third conductive layer 173 may be formed by further performing a planarization process after a process of depositing the preliminary third conductive layer (173p, see FIG. 8I). The third conductive layer 173 may completely fill an upper gap region (not illustrated). By the planarization process, an upper surface of the insulating isolation pattern 130 may be exposed, and an upper surface of the insulating isolation pattern 130 and an upper surface of the third conductive layer 173 may be coplanar with each other. In some example embodiments, the third conductive layer 173 may include a plurality of conductive layers. Accordingly, consequently, the first and second gate electrodes 170A and 170B may be formed.

The gate capping layers 166 may be formed by partially removing the first and second gate electrodes 170A and 170B, the gate dielectric layers 162, and the gate spacer layers 163, filling the removed regions with an insulating material, and performing a planarization process. A relative thickness of the gate capping layers 166 and the shape of lower surfaces thereof may be varied in example embodiments.

Thereafter, the second interlayer insulating layer IL2 may be further formed, and contact plugs 180 connected to the source/drain regions 150 may be formed. Accordingly, the semiconductor device 100 in FIGS. 1 to 2C may be manufactured.

According to the aforementioned example embodiments, by including channel layers of which a portion of a side surface is extended and an insulating pillar of which a portion of a side surface is removed, a semiconductor device having improved electrical properties and reliability may be provided.

While the example embodiments have been illustrated and described above, it will be configured as apparent to those skilled in the art that modifications and variations may be made without departing from the scope in the example embodiment as defined by the appended claims.

What is claimed is:

1. A semiconductor device, comprising:
a substrate including a first region and a second region, the substrate including an active region extending in a first direction;
a device isolation layer defining the active region, the device isolation layer being on the substrate;
a first gate electrode and a second gate electrode extending in a second direction, the second direction intersecting the active region, the first gate electrode and the second gate electrode being spaced apart from each other;
a plurality of first channel layers spaced apart from each other in a third direction, the third direction being perpendicular to an upper surface of the substrate, and the plurality of first channel layers being surrounded by the first gate electrode on the first region;
a plurality of second channel layers spaced apart from each other in the third direction, the plurality of second channel layers being surrounded by the second gate electrode on the second region;
an insulating isolation pattern extending in the first direction between the first gate electrode and the second gate electrode and between the plurality of first channel layers and the plurality of second channel layers, the insulating isolation pattern being on the substrate;
gate dielectric layers between the plurality of first channel layers and the first gate electrode, and the gate dielectric layers between the plurality of second channel layers and the second gate electrode; and
epitaxial layers on side surfaces of the plurality of first channel layers and the plurality of second channel layers that respectively oppose each other, wherein
a portion of each of the epitaxial layers overlap the insulating isolation pattern, the gate dielectric layers, the first gate electrode, and the second gate electrode in the third direction.

2. The semiconductor device of claim 1,
wherein the first gate electrode includes a first conductive layer conformally extending along an upper surface, a side surface, and a lower surface of each of the plurality of first channel layers, respectively, and
wherein the second gate electrode includes a second conductive layer conformally extending along an upper surface, a side surface, and a lower surface of each of the plurality of second channel layers, respectively.

3. The semiconductor device of claim 2, wherein the first conductive layer and the second conductive layer include different metal materials.

4. The semiconductor device of claim 2, wherein
the first gate electrode further includes a third conductive layer on the first conductive layer and between the plurality of first channel layers in the third direction.

5. The semiconductor device of claim 4, wherein the third conductive layer overlaps at least a portion of a corresponding one of the epitaxial layers in the third direction.

6. The semiconductor device of claim 1, wherein
the insulating isolation pattern includes one of silicon oxide, silicon nitride, silicon oxynitride, silicon carbide, or a combination thereof.

7. The semiconductor device of claim 1, wherein the insulating isolation pattern is between the first gate electrode and the second gate electrode.

8. The semiconductor device of claim 1, wherein,
the epitaxial layers include a first one of the epitaxial layers on a side surface of a corresponding one of the plurality of first channel layers and a second one of the epitaxial layers on a side surface of a corresponding one of the plurality of second channel layers,
the first one of the epitaxial layers and the second one of the epitaxial layers are disposed at a same level and spaced apart from each other with the insulating isolation pattern therebetween.

9. The semiconductor device of claim 1, wherein each of the epitaxial layers has a width decreasing in the third direction as the epitaxial layers extend toward the insulating isolation pattern.

10. The semiconductor device of claim 9, wherein a cross-sectional shape of each of the epitaxial layers is one of a triangular shape, a quadrangular shape, or a semicircular shape.

11. The semiconductor device of claim 1, further comprising:
a gate capping layer on an upper surface of the first gate electrode, an upper surface of the second gate electrode, and an upper surface of the insulating isolation pattern.

12. The semiconductor device of claim 1, wherein the epitaxial layers each include a same material as a material of an adjacent one of the plurality of first channel layers or a material of an adjacent one the plurality of second channel layers adjacent to each other.

13. The semiconductor device of claim 1, wherein a portion of a side surface of the insulating isolation pattern extends in the third direction along ends of the epitaxial layers in the second direction.

14. The semiconductor device of claim 13, wherein ends of the epitaxial layers, opposing each other are not in contact with the gate dielectric layers.

15. The semiconductor device of claim 1, wherein a portion of a side surface of the insulating isolation pattern has a convex shape toward an external side on a level between the epitaxial layers on different levels.

16. A semiconductor device, comprising:
a substrate including an active region extending in a first direction;
a first gate electrode and a second gate electrode extending in a second direction, the second direction intersecting the active region, the first gate electrode and the second gate electrode being spaced apart from each other;
a plurality of first channel layers spaced apart from each other in a third direction, the third direction perpendicular to an upper surface of the substrate, and the plurality of first channel layers being surrounded by the first gate electrode;
a plurality of second channel layers spaced apart from each other in the third direction, the plurality of second channel layers being surrounded by the second gate electrode;
an insulating isolation pattern between the plurality of first channel layers and the plurality of second channel layers, the insulating isolation pattern extending to a level lower than a level of an upper surface of the active region;
first epitaxial layers on side surfaces of the plurality of first channel layers and the plurality of second channel layers, opposing each other, the first epitaxial layers being in contact with the insulating isolation pattern in the active region; and
a second epitaxial layer in the active region of the substrate and having an upper surface in contact with the insulating isolation pattern.

17. The semiconductor device of claim 16, wherein the first epitaxial layers and the second epitaxial layer include a same material.

18. The semiconductor device of claim 16, wherein a lower surface of the second epitaxial layer is lower than a level of an upper surface of the active region.

19. A semiconductor device, comprising:
a substrate including a first region and a second region, the substrate including an active region extending in a first direction;
a first gate electrode and a second gate electrode extending in a second direction, the second direction intersecting the active region, the first gate electrode including a first conductive layer, the second gate electrode including a second conductive layer, the first gate electrode and the second gate electrode each including a third conductive layer, the first conductive layer and the third conductive layer of the first gate electrode being stacked in order, and the second conductive layer and the third conductive layer of the second gate electrode being stacked in order;
a plurality of channel layers stacked in a third direction on the active region, the third direction being perpendicular to an upper surface of the substrate, and the plurality of channel layers overlapping the third conductive layer of the first gate electrode in the third direction;
a gate dielectric layer covering a portion of each of the plurality of channel layers;
an insulating isolation pattern between the first gate electrode and the second gate electrode; and
a semiconductor material layer disposed on a side surface of at least one of the plurality of channel layers,
wherein the first conductive layer and the second conductive layer include different metal materials.

20. The semiconductor device of claim 19, wherein
the gate dielectric layer is between the first gate electrode and the insulating isolation pattern and between the second gate electrode and the insulating isolation pattern.
